(19) United States
(12) Patent Application Publication
(10) Pub. No.: US 2011/0003270 A1
(43) Pub. Date: Jan. 6, 2011

(54) IN BREECH TRAINING DEVICE

(76) Inventor: Henry I. Jehan, JR., Lake Mary, FL (US)

Correspondence Address: PATTERSON THUENTE CHRISTENSEN PEDERSEN, P.A., 4800 IDS CENTER, 80 SOUTH 8TH STREET, MINNEAPOLIS, MN, 55402-2100, US

(21) Appl. No.: 11/840,760

(22) Filed: Aug. 17, 2007

(51) Int. Cl. F41G 3/26; H05K 13/00

(52) U.S. Cl. 434/19; 29/592.1

(57) ABSTRACT

An in breech training device for use with an emitter communicator for emitting an emission and receiving a return communication, includes a sleeve, disposable in a chamber of a gun barrel of a gun, the sleeve having an emitter receiver defined therein, and the emitter being disposable in the emitter receiver such that an emission emitted from the emitter communicator is automatically aligned with the gun barrel by the sleeve. A method of forming an in breech training device is further included.

### TECHNICAL FIELD

Present invention relates to training devices useful by military forces. More particularly, the present invention relates to training devices utilized in direct-fire training by military forces.

### BACKGROUND OF THE INVENTION

There is presently a training device known by the acronym MILES, which stands for Multiple Integrated Laser Engagement System. The MILES training device is presently used by military organizations worldwide for live force-on-force direct-fire training. Historically, equipping a combat system with MILES training hardware required the installation and alignment of the laser emitter to the gun tube using a time consuming and cumbersome manual process that often took many hours to accomplish. The process required the manual adjustment of the laser emitter mounting assembly so that, when viewed through an attached telescope, the gun tube and laser were aligned. In other respects, the MILES device is a very useful training device.

There is a need then to simplify the integration of the MILES device with a weapon system. There is a need to package the MILES emitter in a way that does not add any training unique tasks for the weapons system crew members and does not omit any tasks critical to the use of the weapons system in combat. The implementation for a particular weapons system, for example the 120 mm smooth-bore cannon on the Abrams tank, has to allow the device to be used interchangeably without manual alignment of the emitter to the weapons system, across the fleet of vehicles (i.e., the Abrams tank in this example) it was designed/sized for while maintaining alignment accuracy between the laser and the weapon of approximately 0.5 milliradians.

Installing a laser transmitter in a gun tube is known. MILES lasers have been installed in the open breech of tank guns for some time. However, the installation process requires manual manipulation and adjustment to firmly seek the emitter device in the breech, followed by the manual alignment of the MILES laser emitter with the gun tube using a telescopic rifle site.

The idea of creating a gun tube alignment device by putting a laser emitter in a shell casing is also known. Laser Shot, an Australian company, manufactures and sells a battery powered visible laser mounted in the shell casing that, when chambered in a rifle or pistol, shoots visible laser beam out of the barrel making a dot on the target similar to the dot created by a laser pointer. By using this device, the sites of the rifle or pistol can be zeroed without firing ammunition. It should be noted however that this product is only made for small caliber weapons. Additionally, it is only a laser pointer, not a laser communicator, so it is totally self-contained. Because it projects a circular beam, it chambers in the weapon without concern for rotational orientation. NBG, Inc., of Hazlehurst, Ga. manufactures and markets a look-a-like product domestically.

SAAB has developed and markets a tactical engagement training system that competes with MILES and employs an alternative technical approach. The SAAB approach is to mount a scanning laser in the muzzle of the gun tube. The SAAB system is mechanically aligned to the gun tube by the insert that attaches it to the muzzle. However, because it employs a scanning laser, it does not have precision alignment requirement required by MILES. For this reason, the SAAB solution is neither compatible with MILES nor applicable to the object of providing a capability that eliminates the laborious manual alignment procedure historically used to align MILES emitters to weapons systems.

Further, American Apex, a U.S. company, uses an o-ring interface to make an in-bore device that aligns a 50 caliber rifle with the barrel of the tank main gun. This device is useful for aligning two guns and is not designed to align a laser with a gun.

### SUMMARY OF THE INVENTION

The in breech training device of the present invention substantially meets the aforementioned needs of the industry. The training device is a marriage of MILES and In-Bore-Technologies. The training device may include the MILES laser emitter assembly mounted in a cylindrical sleeve, the sleeve being sized to fit into the breech of the weapons system so that the laser beam emitted by the MILES laser emitter is directed along the longitudinal axis of the gun tube and out the muzzle thereof. At least two O rings mounted on the cylindrical sleeve provide a self-centering support for the cylindrical sleeve and provide constant seating to maintain accuracy throughout a training event. The MILES emitter, when mounted in the cylindrical sleeve, is automatically aligned with the center line of the gun tube so that the laser beam traverses the center of the gun tube.

The training device of the present invention eliminates the need for conducting the laborious alignment process previously needed when employing a MILES laser emitter device. The MILES laser emitter is centrally mounted in a cylindrical device. The cylindrical device can then be loaded into the breech of the gun as if it were a round of ammunition. Because the cylindrical device seats into the forcing cone in the back of the breech through the use of self-centering O rings, the laser emitter is accurately and automatically aligned with the longitudinal axis of the barrel without the use of any manual process.

Because the MILES laser emitter pattern is wider than it is tall, rotational orientation of the MILES laser emitter with respect to the gun tube must be maintained. The rotational orientation of the MILES laser emitter is maintained by a loader interface box that attaches to the cylindrical device. The loader interface box includes a reset switch to force the simulation of the normal loader functions when the weapon is being fired with live ammunition.

The training device of the present invention is applicable to any direct-fire weapon which the bore is large enough to house a MILES emitter where the MILES emitter can be configured to be eye-safe over the range of the specific direct-fire weapon.

The present invention is an in breech training device for use with an emitter communicator for emitting an emission and receiving a return communication, and includes a sleeve, disposable in a chamber of a gun barrel of a gun, the sleeve having an emitter receiver defined therein, and the emitter being disposable in the emitter receiver such that an emission emitted from the emitter communicator is automatically aligned with the gun barrel by the sleeve. The present invention is further a method of forming an in breech training device.

### BRIEF DESCRIPTION OF THE DRAWINGS

FIG. 1 is a perspective depiction of the training device of the present invention disposed in a sectioned gun assembly;

FIG. 2 is an elevational breech and depiction of the training device mounted in gun assembly;

FIG. 3a is a perspective view of an eye-safe dual laser MILES emitter with the top cover removed;

FIG. 3b is a perspective depiction of the MILES emitter of FIG. 3a;

FIG. 4 is an elevation depiction of the training device with the components thereof in the disassembled disposition;

FIG. 5 is a perspective view of the training device being mounted in the breech of a 120 mm cannon; and

FIG. 6 is a perspective view of the training device mounted in the breech of a 120 mm cannon; and

FIG. 7 is an elevational breech-end view of a training device mounted in the 120 mm cannon.

### DETAILED DESCRIPTION OF THE DRAWINGS

An exemplary gun assembly is depicted at 10 in the FIGS. The exemplary gun assembly 10 is a 120 mm smooth-bore cannon that is mounted on an Abrams tank. It is understood that the training device 30 of the present invention may be used in any gun which has dimensions at the breech that are large enough to accept the MILES laser emitter 70.

Gun assembly 10 includes a barrel 12. The barrel 12 has a longitudinal bore 13 defined therein that terminates in a chamber 14 proximate the breech end of the barrel 12.

A transversely shiftable breech block 18 is disposed at the breech 16. The breech block 18 is depicted in the FIGS. in the open disposition. It should be noted the breech block 18 remains in the open disposition throughout operations of the training device 30, described below. A breech mortis 20 is defined in the breech block 18. The breech mortise 20 includes two parallel spaced apart flat sides 22 joined at the bottom by a semi-circular bottom 24. In the open disposition that is depicted, a round of ammunition may be inserted into the chamber 14 or an expended shell casing may be extracted from the chamber 14.

The In-bore training device of the present invention is shown generally at 30 in the FIGS. The training device 30 includes an elongate sleeve 32. The sleeve 32 may be formed of a shell casing adapted to fit the chamber 14 of the particular gun assembly 10 in which the training device 30 is to be employed or sleeve 32 may be specially manufactured for use as a component of the training device 30. The sleeve 32 includes a sleeve bore 34 defined therein that extends to an opening 35 at the forward or muzzle end of the sleeve 32.

The sleeve 32 includes a front land 36. The front land 36 includes at least one O ring 38 that is compressed on the training device 30 as the training device 30 is inserted into the chamber 14. Such compression between the chamber 14 wall and the sleeve 32 acts to automatically center the training device 30 in the chamber 14. The sleeve 32 further includes a rear land 40 and at least one O ring 42. The O ring 42 performs the same function as the O ring 38 noted above.

The sleeve 32 includes a breech face 44 that is generally circular in shape and is disposed transverse to the longitudinal axis of the sleeve 32, such axis being coincident with the longitudinal axis 43 of the barrel 12. A breech ring 45 is selectively matable to the breech base 44. An emitter receiver 46 is defined interior to rear land 40 and forward of the breech face 44. The emitter receiver 46 is generally rectangular in shape to conform closely to the exterior dimensions of the laser emitter 70, to be described below. The receiver 46 has a forward directed aperture 47, through which laser emissions may pass. The emitter receiver 46 is disposed within the sleeve 32 such that when the laser emitter 70 is positioned within the emitter receiver 46 a laser emission emitted from the laser 70 is automatically aligned with the longitudinal axis 43 of the barrel 12 to very tight tolerances.

A handle assembly 52 is affixable to the sleeve 32 to accommodate the ready insertion of the training device 30 into the breech 16. The handle assembly 52 includes a grip 54 the grip 54 is generally transverse to the longitudinal axis of the training device 30. The grip 54 is affixed to a generally horizontal support 56 at a right-angle connection. A cross-brace 58 is affixed to the horizontal support 56. The handle assembly 52 is coupleable to the sleeve 32 by means of bolts 60 that pass through bores defined in the cross bores 58, through bores in registry therewith defined in the breech ring 45, and thence threaded into the breech face 44. The handle assembly 52 facilitates insertion of the training device 30 into the breech 16 as depicted in FIG. 5.

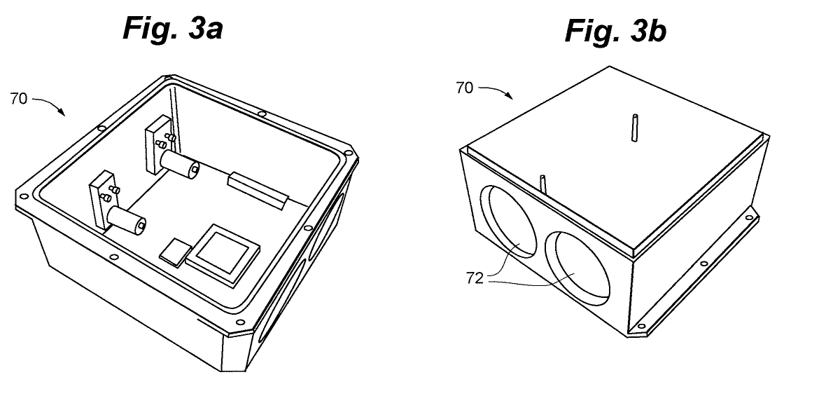

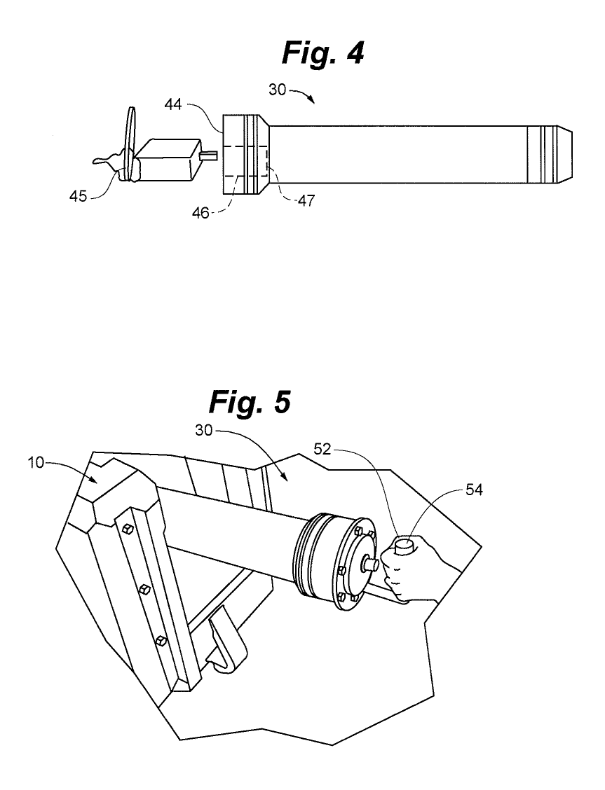

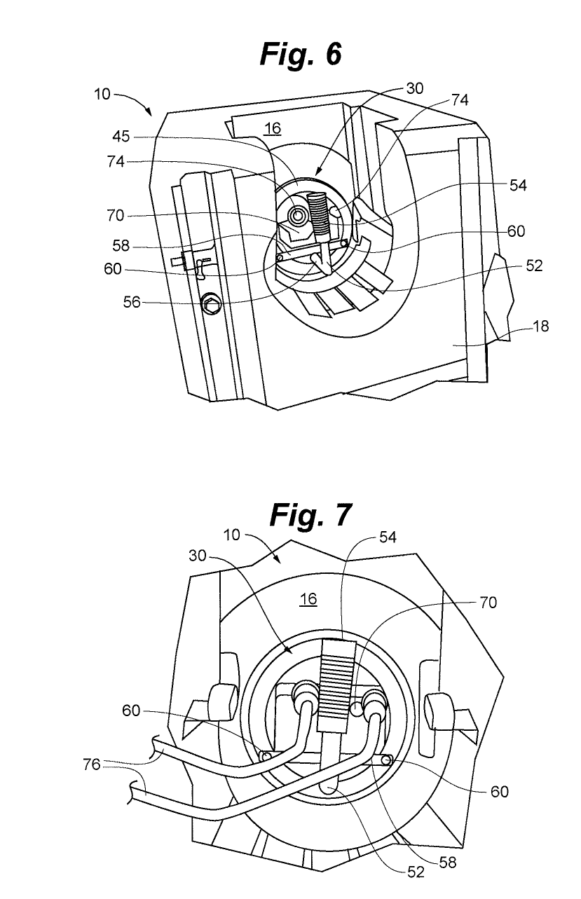

Referring to FIGS. 3a and 3b, laser emitter 70 is depicted. The exemplary laser emitter 70 is a known laser emitter that is marketed under the acronym MILES. Other laser emitters could as well be used with the training device 30 The MILES laser emitter 70 is a communicator in that it communicates the results of simulated direct-fire rounds to the operators of the gun assembly 10. It is important that the laser emitter employed with the in breech training device 30 be eye-safe. Theoretically, a single laser emitter could be mounted in the sleeve 32 to simulate the weapon engagement. However, the laser energy levels required by the MILES standard for engagements at the ranges of the exemplary 120 mm cannon exceed the limits for eye-safety. To overcome this limitation, the eye-safe dual laser assembly illustrated in FIGS. 3a, 3b may be utilized at extended ranges. It should be noted that the laser emitter 70 includes two laser apertures 72. As depicted in FIGS. 6 and 7, the laser emitter 70 includes a pair of electrical connectors 74. The electrical connector 74 may be coupled to connector wires 76. The connector wires 76 convey power to the laser emitter 70 to effect the emission of a laser beam. Additionally, the connector wire 76 conveys returned communications from the laser emitter 70 to the operators of the in bore training device 30.

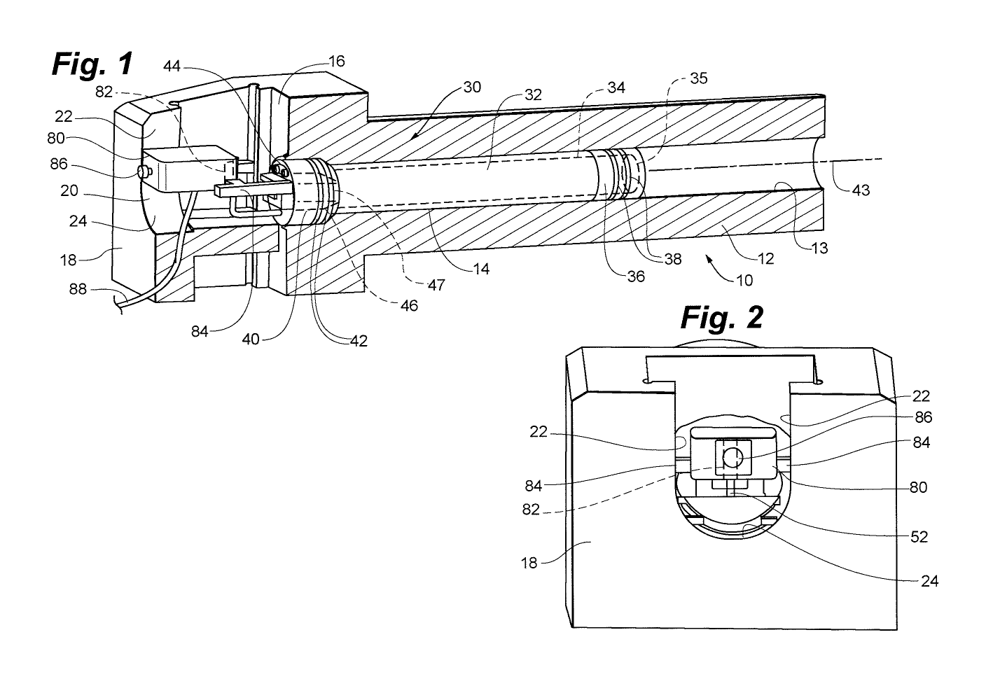

As depicted in FIGS. 1 and 2, loaders interface box 80 is coupleable to the sleeve 32. The loader interface box includes a handle capture slot 82. When the loader interface box 80 is mated to the sleeve 32, the grip 54 of the handle assembly 52 is captured within the handle capture slot 82. The loader interface box 80 includes a pair of opposed t-shaped side supports 84. As depicted in FIG. 2, the side supports 84 engage respective parallel flat sides 22 of the breech mortise 20, thereby fixing the in bore training device 30 within the breech 16 with respect to roll of the gun assembly 10. Such support is necessary to ensure that the in breech training device does not roll with respect to the barrel 12 during rolling maneuvers of the vehicle on which the gun assembly 10 is installed.

The loader interface box 80 further includes a load simulator 86 which may be actuated by the loader member of the gun crew to simulate loading a round in the gun assembly 10. The simulated loaded condition may be transmitted to other members of the crew by means of the connector 88.

In Assembly/operation, the emitter 70 is disposed in the receiver 46 and fixed in place by the breech ring 45. The training device 30 may then be inserted into the chamber 14. A loader may cradle the sleeve 32 with one handle and grasp the handle 54 with the other, as depicted in FIG. 5, during loading of the training device 30. The loader's interface box 80 may the be coupled to the sleeve 32 by engagement with the handle 52. The handle 52 may have to be rotated a bit one way or the other at this point to square the sleeve 32 in the chamber 14. Once the handle 52 is captured by the loader's interface box 80, the sleeve 32 is os squared and the sleeve 32 is locked with respect to rolling motion imparted the gun assembly 10 by rolling motion of the vehicle.

The present invention may be embodied in other specific forms without departing from the spirit of the essential attributes thereof; therefore, the illustrated embodiments should be considered in all respects as illustrative and not restrictive, reference being made to the appended claims rather than to the foregoing description to define the scope of the invention.

1. An in breech training device, comprising:
a sleeve, disposable in a chamber of a gun barrel of a gun, the sleeve having an emitter receiver defined therein; and
an emitter communicator for emitting an emission and receiving a return communication, the emitter being disposable in the emitter receiver such that an emission emitted from the emitter communicator is automatically aligned with the gun barrel by the sleeve.

2. The training device of claim 1, the sleeve being aligned with a bore axis by means of at least one O ring held in compression between the sleeve and the chamber.

3. The training device of claim 1, the sleeve being formed to replicate a shell casing of a round chambered for the gun.

4. The training device of claim 3, the sleeve being loadable into the chamber in a manner similar to the loading of a round chambered for the gun.

5. The training device of claim 1, the sleeve being lockable in the chamber with respect to rolling motion of the barrel.

6. The training device of claim 1, the emitter communicator being automatically aligned with a bore axis by means of insertion of the sleeve containing the emitter communicator into the chamber.

7. The training device of claim 1, a loader interface box being couplable to the sleeve, the loader interface box for simulating a round loading operation by a gun crew.

8. The training device of claim 7, the loader interface box having support means for locking the sleeve in the chamber with respect to rolling motion of the barrel.

9. An in breech training device for use with an emitter communicator for emitting an emission and receiving a return communication, comprising:
a sleeve, disposable in a chamber of a gun barrel of a gun, the sleeve having an emitter receiver defined therein; and
the emitter being disposable in the emitter receiver such that an emission emitted from the emitter communicator is automatically aligned with the gun barrel by the sleeve.

10. The training device of claim 9, the sleeve being aligned with a bore axis by means of at least one O ring held in compression between the sleeve and the chamber.

11. The training device of claim 9, the sleeve being formed to replicate a shell casing of a round chambered for the gun.

12. The training device of claim 11, the sleeve being loadable into the chamber in a manner similar to the loading of a round chambered for the gun.

13. The training device of claim 9, the sleeve being lockable in the chamber with respect to rolling motion of the barrel.

14. The training device of claim 9, the emitter communicator being automatically aligned with a bore axis by means of insertion of the sleeve containing the emitter communicator into the chamber.

15. The training device of claim 9, a loader interface box being couplable to the sleeve, the loader interface box for simulating a round loading operation by a gun crew.

16. The training device of claim 15, the loader interface box having support means for locking the sleeve in the chamber with respect to rolling motion of the barrel.

17. A method of forming an in breech training device for use with an emitter communicator for emitting an emission and receiving a return communication, comprising:
forming a sleeve to be disposable in a chamber of a gun barrel of a gun and defining an emitter receiver in the sleeve; and
disposing the emitter in the emitter receiver such that an emission emitted from the emitter communicator is automatically aligned with the gun barrel by the sleeve.

18. The method of claim 17, including aligning the sleeve being with a bore axis by means of at least one O ring held in compression between the sleeve and the chamber.

19. The method of claim 17, including forming the sleeve to replicate a shell casing of a round chambered for the gun.

20. The method of claim 17, including automatically aligning the emitter communicator with a bore axis by means of insertion of the sleeve containing the emitter communicator into the chamber.
